(19) United States
(12) Patent Application Publication
(10) Pub. No.: US 2009/0206320 A1
(43) Pub. Date: Aug. 20, 2009

(54) GROUP III NITRIDE WHITE LIGHT EMITTING DIODE

(75) Inventors: Soo Jin Chua, Singapore (SG); Peng Chen, Singapore (SG); Eiryo Takasuka, Hyogo (JP)

Correspondence Address: FULWIDER PATTON LLP, HOWARD HUGHES CENTER, 6060 CENTER DRIVE, TENTH FLOOR, LOS ANGELES, CA, 90045, US

(73) Assignee: Agency for Science, Technology and Research, Matrix (SG)

(21) Appl. No.: 11/909,613

(22) PCT Filed: Mar. 24, 2005
(86) PCT No.: PCT/SG2005/000099

§ 371 Date: Mar. 6, 2009

(51) Int. Cl. H01L 29/06; H01L 21/00

(52) U.S. Cl. 257/13; 438/47; 438/34; 257/E21.002; 257/E31.021

(57) ABSTRACT

A white light-emitting diode is fabricated by metal organic chemical vapor deposition (MOCVD), which can produce a broad band emission covering all the visible range in the spectrum by capping the Indium nitride (InN) and Indium-rich Indium Gallium Nitride (InGaN) quantum dots (QDs) in single or multiple InₓGa₁₋ₓN/In_{y}Ga_{1-y}N quantum wells (QWs) by introducing bursts of at least one of Timethylindium (TMIn), Triethylindium (TEIn) and Ethyldimethylindium (EDMIn), which serve as nuclei for the growth of QDs in QWs. The diode can thus radiate white light ranging from 400 nm to 750 nm by adjusting the In burst parameters.

### FIELD OF THE INVENTION

The invention relates to optoelectronic devices and fabrication methods, particularly to white light emitting diodes.

### BACKGROUND

Light emitting diodes (LEDs) are widely used in optical displays, traffic lights, data storage, communications and medial applications. Current applications of white LEDs include instrument panels of motor vehicles and liquid crystal display (LCD) backlighting. An important goal for white LEDs is to increase the luminosity level to allow replacement of incandescent lamps, because LEDs are smaller, have higher efficiency, and have about a 50 times longer life span as compared to conventional light bulbs.

Conventional white LEDs are usually fabricated according to two methods. In one method, three separate LED chips are enclosed in a single LED body where a red chip, a blue-green chip and a blue chip combine emissions to yield white light.

Another widely used method of producing white LEDs entails using a single high-bright blue or UV GaN-based LED chip that has been coated with phosphors or organic dyes. However the use of fluorescent material introduces reliability problems and energy losses from the conversion of blue photons to yellow photons. Also, the packaging step becomes critical for producing consistency in the color characteristic and quality of the LED.

A conventional approach to producing white light-emitting diodes has been explored by Chen et al. (U.S. Pat. No. 6,163,038). This patent describes a white LED and a method of fabricating the white LED that can radiate white light itself by possessing at least two energy bandgaps in the structure of the LED. However, this technology only uses Multiple Quantum Wells (MQW) to get the white emission. Chen et al. only mentions growing the MQWs emitting light with different colors by adjusting growth parameters, not specifying how to achieve it. Chen et al. fails to produce MQWs emitting light covering all the visible range. That is, Chen et al. merely uses a single LED ship to produce light at plural peaks of the spectrum, which are then combined. Thus, it is necessary to use a specific wavelength of light (e.g., 370-500 nm), to serve as a base.

A related art technology, for producing enhanced LEDs has been proposed by Chua et al. (U.S. Pat. No. 6,645,885), which pertains to forming indium nitride (InN) and indium gallium nitride (InGaN) quantum dots grown by metal-organic vapor phase epitaxy. This patent describes indium nitride (InN) and indium-rich indium gallium nitride (InGaN) quantum dots embedded in single and multiple InₓGa₁₋ₓN/In_{y}Ga_{1-y}N quantum wells (QWs) formed by using at least one of trimethylindium (TMIn) triethylindium (TEIn) and ethyldimethylindium (EDMIn) as an antisurfactant during MOCVD growth, and the photoluminescence wavelength from these dots ranges from 480 nm to 530 nm. Controlled amounts of TMIn and/or other Indium precursors are important in triggering the formation of dislocation-free QDs, as are the subsequent flows of ammonia and TMIn. This method can be used for the growth of the active layers of blue and green light emitting diodes (LEDs). However, this technology fails to produce a diode that generates white light. White light requires a range of 400 to 750 nm. However, the technology of Chua et al. only covered the lesser wavelength range of 480 nm to 530 nm and could not be used to generate white light.

Accordingly, modern semiconductor and display technology requires new white light-emitting diodes that are easy to construct, have high luminosity and have the necessary reliability to serve in exacting applications such as light sources for liquid crystal display devices.

### SUMMARY OF THE INVENTION

Accordingly, the invention is directed to producing a white light-emitting diode (LED) that substantially obviates one or more problems due to limitations and disadvantages of the related art.

An object of the invention is to provide an LED that incorporates all emissions into one chip.

The invention, in part, pertains to a white-light emitting diode, comprising a substrate; a buffer layer formed over the substrate, the buffer layer being divided into a first section and a second section; at least one quantum well structure comprising a InₓGa₁₋ₓN/In_{y}Ga_{1-y}N quantum well/barrier bilayer that encompasses InN and indium-rich InGaN quantum dots, formed over the first section of the buffer layer; a p-type semiconductor formed over the at least one quantum well structure; a first electrode formed over the p-type semiconductor; and a second electrode formed over at least a portion of the second section of the buffer layer.

In the invention, the quantum dots are formed by first flowing at least one of TMIn, TEIn or EDMIn at a first flow rate and a first time to form nuclei, and then flowing at least one of TMIn, TEIn or EDMIn with TMG and ammonia at a second flow rate to make the nuclei grow and be capped in the quantum wells. There can be between about 1 to 30 of the quantum well structures. Also, a thickness of the InₓGa₁₋ₓN quantum well layer can be about 1 to 10 nm and a thickness of the In_{y}Ga_{1-y}N quantum barrier layer is about 5 to 30 nm, and 1>x>y>0 or y=0. The substrate can be sapphire. Sic or ZnO. At least one of biscyclopentadienyl magnesium, diethyl zinc or silane can be used as dopants. The inventive diode emits light in a range of about 400 nm to 750 nm.

The invention, in part, pertains to a quantum well structure that emits white light, which comprises an InₓGa₁₋ₓN quantum well layer; indium-rich InGaN quantum dots embedded in the InₓGa₁₋ₓN quantum well layer; and an In_{y}Ga_{1-y}N quantum barrier layer over the quantum dots and the quantum well layer.

The invention, in part, pertains to process for forming a white-light emitting diode, which comprises providing a substrate; forming a buffer layer formed over the substrate, the buffer layer being divided into a first section and a second section; forming at least one quantum well structure comprising a InₓGa₁₋ₓN/In_{y}Ga_{1-y}N quantum well/barrier bilayer that encompasses InN and indium-rich InGaN quantum dots, formed over the first section of the buffer layer; forming a p-type semiconductor over the at least one quantum well structure; forming a first electrode over the p-type semiconductor; and forming a second electrode over at least a portion of the second section of the buffer layer.

In the invention, the quantum dots can be formed by the steps of flowing at least one of TMIn, TEIn or EDMIn at a first flow rate and a first time to form nuclei; and flowing at least one of TMIn, TEIn or EDMIn with TMG and ammonia at a second flow rate to make the nuclei grow and be capped in the quantum wells. Also, different flow rates of TMIn, TEIn or EDMIn produce quantum wells of different sizes.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

It is to be understood that both the foregoing general description and the following detailed description of the invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention.

In the drawings:

FIG. 1 shows a diagram of a white LED having QD-capped MQWs at the active layer in accordance with the invention;

FIG. 2 shows the room temperature photoluminescence spectrum of a white LED in accordance with the invention; and

FIG. 3 shows a diagram of a white LED having QD-capped MQWs at the active layer in accordance with an embodiment of the invention.

### DETAILED DESCRIPTION

Reference will now be made in detail to the preferred embodiments of the invention, examples of which are illustrated in the accompanying drawings.

The invention fabricates a diode using epitaxial techniques. The inventive diode utilizes quantum dots to produce electroluminescence from the PN junction having a broad peak from 400 nm to 750 nm.

Quantum dots can be defined as a particle of matter so small that the addition or removal of an electron changes its properties in some useful way. Alternately, quantum dots can be view as very small devices that confine, i.e., cage, a small number (as few as one) of free electrons. Quantum dots typically have dimensions on the order of nanometers. That is, quantum dots can have a size range of 5 to 200 nm, with 20-80 nm being typical in many applications.

Using epitaxial growth processes, quantum dots can be grown with confinement provided in all three dimensions by a high bandgap in the surrounding material. In lithographically defined quantum dots, a quantum well provides a confining potential along the growth direction while an electrostatically induced potential barrier provides the lateral confinement.

The epitaxial growth of thin films or quantum dots of nitrides or oxides can be accomplished using metalorganic chemical vapor deposition (MOCVD). MOCVD uses a carrier gas flow containing a dilute mixture of metal organic precursors. The gas mixture flows into a reactor chamber at 50-500 torr where substrates are at 500-1200° C. for conventional Group III-V materials. Ammonia (NH₃) can be used as the nitrogen source for forming nitrides such as GaN or GaIn. The reactive gases decompose and deposit thin epitaxial layers of III-V materials (e.g., AlGaN, InGaInN, InGaN, etc.) from a few nanometers to a few microns thick, as required.

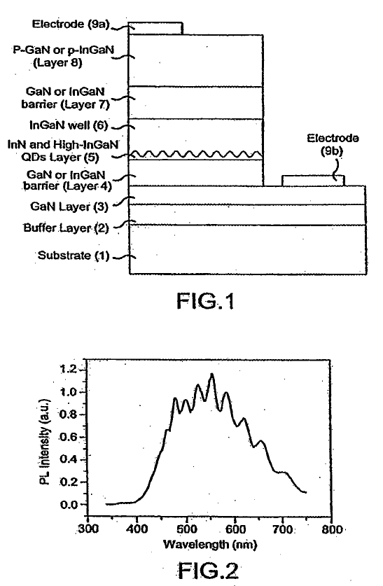

FIG. 1 is a diagram showing a white light emitting diode in accordance with the invention.

FIG. 1 shows a substrate 1 which can be sapphire, silicon carbide (Sic), zinc oxide (ZnO) or other substrates. Buffer layer 2 is the low-temperature GaN buffer, and layer 3 is formed from undoped GaN or Si-doped GaN grown at around 1000° C. Layer 4 is a GaN or InGaN barrier layer. After the barrier layer 4 is grown, TMIn and ammonia were flowed to form a “seed” for the growth of indium rich QDs 5. Layer 6 is a quantum well having high iridium content, over which is another GaN or InGaN barrier layer 7. Layer 8 is formed from Mg-doped GaN grown at around 1000° C. or Mg-doped InGaN grown in a temperature range of about 750° C.±100° C. The first electrode 9a is formed on the top of the p-type GaN or p-type InGaN layer 8. A second electrode 9b is formed over the n-type GaN layer 3.

In FIG. 1, layer 1 may be any material suitable for the growth of GaN, such as sapphire, SiC, ZnO, GaN and other alternatives. Layer 2, the low temperature buffer, can also be the multi-layered AlGaN/GaN buffer. Layer 3 can be undoped GaN, Si doped GaN, or Mg doped GaN. Layers 4 and 7 can be InGaN with low indium content instead of GaN. Layer 8 is the high temperature grown Mg doped GaN or Mg-doped InGaN, or Zn-doped GaN or Zn-doped InGaN.

The relatively rough surface of the low-temperature (LT) GaN or InGaN layer (layer 4 in FIG. 1) could help keep the impinging indium atoms, which come from the cracking (decomposition) of the TMIn precursor, stay longer on the surface, thereby increasing the indium incorporation, which will also result in the red-shift in the emission.

Although trimethyl indium (TMIn) is frequently used as the precursor, other indium organometallic compounds can be used, such as triethylindium (TEIn) and ethyldimethylindium (EDMIn). These organometallic compounds can be used singly or in mixtures.

One of the aspects of the inventive technology is referred to as In burst. In the invention, In burst forms indium-rich QDs (quantum dots) capped in InₓGa₁₋ₓN/GaN or InₓGa₁₋ₓN/In_{y}Ga_{1-y}N single or multiple quantum wells, which normally emit long wavelength light (yellow and red). The QDs are induced by flowing TMIn (trimethyl indium) or other indium precursors acting as nuclei. The white emission can be obtained by varying the wavelength and the intensity of the emission distribution, which can be achieved by adjusting the epitaxial growth parameters, such as temperature, reactor pressure, NH₃ flux, the In flux and duration during the In burst and the InGaN quantum well growth. That is, by varying the parameters, quantum dots of varying indium content and size can be formed.

Two considerations are of interest when forming Indium rich QDs. First, the amount of TMIn acting as nucleus and the duration of the TMIn flow are important. Too much flow will create indium droplets, which compete with the formation of Indium-rich QDs. The quantum confinement effect of the QDs is the reason why QDs have very high luminescence efficiency at room temperature. Second, the subsequent flows of TMIn, TMGa and ammonia are also very important for the formation of QDs and the quantum well with the QDs capped in it. Usually, the growth should be conducted with a high partial pressure of ammonia.

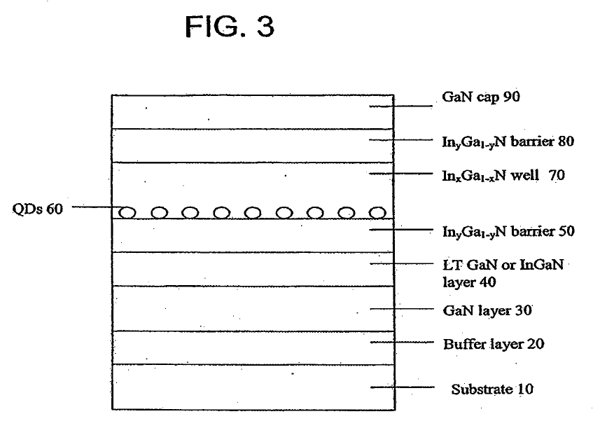

FIG. 3 shows another preferred embodiment of the invention.

In FIG. 3, layer 10 shows a substrate, which is preferably sapphire, SiC or ZnO. Layer 20 is a low-temperature buffer grown at about 450° C. to 600° C. Layer 30 can be undoped GaN or Si-doped GaN, grown at around 1030° C. Layer 40 is a GaN or InGaN grown at the same temperature as the barrier and well. Layer 50 is a In_{y}Ga_{1-y}N barrier, wherein y preferably ranges from 0.01 to 0.1 grown at about 700° C. to 800° C. After the growth of layer 5, indium rich QDs 60 are formed using In bursts. Over the QDs is formed layer 70, the InₓGa₁₋ₓN quantum well where x is greater than y. Layer 80 is another In_{y}Ga_{1-y}N barrier typically similar to layer 50. Layer 90 is a p-GaN or p-InGaN cap grown at temperatures in the range of between 700° C. and 1100° C.

In FIG. 3, layer 10 may be any material suitable for the growth of GaN, such as sapphire, SiC, ZnO, and other alternatives with thickness of about 200 μm to 500 μm. Layer 20, the low temperature buffer which is about 20 nm to 100 nm thick, can also be a multi-layered AlGaN/GaN buffer. Layer 30 can be un-doped GaN, or Si-doped GaN to a concentration 2×10¹⁷ cm⁻³ to 9×10¹⁸ cm⁻³, or Mg doped GaN to a concentration of 5×10¹⁷ cm⁻³ to 3×10²⁰ cm⁻³, and its thickness ranges from 1 μm to 10 μm. Layer 40 can be GaN, InGaN or AlGaN grown at the same temperature as the barrier and well with a thickness of about 5 nm to 30 nm. Layers 50 and 70 can be GaN instead of InGaN. Layer 90, the 10 nm to 1000 nm thick cap, can also be AlGaN.

The insertion of the layer 40 in FIG. 3 is important to extend the luminescence range. Without being bound by any theory of the invention, it is thought that the low temperature GaN layer (layer 40 in FIG. 3) partially relaxes the compressive strain between the InGaN well and barrier. This relaxation of compressive strain can result in a phase shift in the luminescence. Relaxation of the compressive strain can also enhance the InGaN phase separation according to Kaprov's (MRS Internet J Nitride Semicond. Res. 3, 16 (1998)) theory, in which compressive strain can suppress the InGaN phase separation.

The relatively rough surface of the low-temperature (LT) GaN layer (layer 40 in FIG. 3) could help keep the impinging indium atoms, which come from the cracking of TMIn precursor, on the surface for a longer time, thereby increasing the indium incorporation which will also result in phase shifting of the luminescence.

A method for growing a white light-emitting LED according to a preferred embodiment of the invention will be described below.

First, a low temperature buffer and then a high temperature n-type GaN layer are grown over a sapphire substrate, with the latter performed usually at about 1000° C. The temperature is next lowered to about 700° C. to 800° C. to grow the GaN or InGaN barrier layer. A low temperature grown buffer is needed when they are grown on a sapphire substrate.

After the growth of the barrier layer, an appropriate amount of TMIn or other indium organometallic precursor(s) is flowed into the reaction chamber in the presence of ammonia. Indium atoms from TMIn aggregate at the atomic surface of the InGaN barriers to form the “seeds” for the subsequent growth of QDs,

In a preferred embodiment of the invention, one white LED was grown by MOCVD on (0001) sapphire substrates. MOCVD was performed using TMG (trimethyl gallium), TMIn (trimethyl indium) and NH₃ (ammonia) as precursors. For this white LED, a 2 μm thick undoped bulk GaN was first grown on the 25 nm thick GaN buffer layer. The growth temperatures are 530° C.±30° C. and 1050° C.±50° C., respectively, for the GaN buffer and bulk layer. After the growth of the GaN bulk layer, the growth temperature was lowered down to about 700° C.±50° C. for the deposition of a GaN or InGaN barrier and an InGaN well. The indium content in the InGaN barrier is less than that in the well. After the growth of the GaN or InGaN barrier, and prior to the growth of high indium content well, TMIn was flowed for a short time, varying from 2 to 5 seconds with the TMGa flow switched off. This process is referred to as In burst. Such a burst will create seeds for the growth of InGaN QDs with varying sizes and indium compositions. The burst duration can be varied for forming the seeds in each layer. The well thickness was about 3 nm. The growth of GaN barrier, the In burst and the InGaN well were repeated three more times.

The In burst can be performed for any appropriate time varying from 0.5 seconds to 1 minute or more. However, 2 to 5 seconds are preferred for the In burst time. A preferable flow rate of the organometallic indium compound is less than 100 μmol/min during the In burst. The well thickness can be about 1-10 nm, preferably 2-4 nm and most preferably about 3 nm

Then, a high temperature Mg doped GaN layer was grown on the top of four periods of InₓGa₁₋ₓN/GaN MQW. The carrier gas was H₂ and N₂ respectively for the growth of GaN and InGaN. Finally, a first electrode is formed on the p-type semiconductor, and a second electrode is formed on a section of the Si doped GaN layer.

Different organometallic materials can be used for doping different structures of the invention. Biscyclopentaldienyl magnesium (CP₂Mg) can be used to produce Mg-doped GaN in, for example, layer 3 or layer 8 in FIG. 1. Diethyl zinc (DEZn) can also be used to provide, for example, the p-doping in layer 8. Silane can also be used as a dopant, for example, to form Si-doped GaN in layer 3.

The example of the preferred embodiment used four quantum well structures. However, any appropriate number of quantum well structures can be used. Practically, 1 to 60 quantum well structures can be used. Preferably 1 to 30 are used.

In the invention, the thickness of the InₓGa₁₋ₓN quantum well layer is in the range of 0.5 to 20 nm and is preferably 1 to 10 nm. The thickness of the In_{y}Ga_{1-y}N barrier layer can be in the range of 2 to 60 nm and is preferably 5 to 30 nm. In a preferred embodiment of the invention, the InₓGa₁₋ₓN quantum well layer has a larger composition than the In_{y}Ga_{1-y}N barrier layer such that 1>x>y>0 or y=0.

FIG. 2 shows the photoluminescence spectrum of a white LED formed according to a preferred embodiment of the invention. FIG. 2 shows a wavelength range of emission that is from 400 nm to 750 nm, which covers the primary colors of blue, green and red. As a result, the diode produces white light.

That is, the inventive diode can radiate white light ranging from about 400 nm to 750 nm by adjusting the In burst parameters such as the amount of In precursors, the burst duration and the temperature. The white LED radiates white light by itself and does not require the combination of separate LEDs or, alternately, the utilization of a white light-emitting fluorescent material. The inventive LED is thus cheaper, more convenient to fabricate, more stable and has a longer lifetime.

As a result, the invention offers clear advantages over the conventional art emitting devices, which have single emitting centers so that white light can only be obtained by combining several devices or by color conversion using a phosphor. In contrast, the invention utilizes quantum dots of different sizes to yield different color lights that combine on a single chip to yield white light. The invention therefore offers compactness, efficiency, luminosity and low cost.

It will be apparent to those skilled in the art that various modifications and variations can be made in the liquid crystal display device using dual light units of the invention without departing from the spirit or scope of the invention. Thus, it is intended that the invention covers the modifications and variations of this invention provided they come within the scope of the appended claims and their equivalents.

1. A diode for emitting white-light, the diode comprising:
a substrate;
a buffer layer formed over the substrate, the buffer layer being divided into a first section and a second section; and
at lease one quantum well structure comprising a modified InₓGa₁₋ₓN/In_{y}Ga_{1-y}N quantum well/barrier bilayer that encompasses InN and indium-rich InGaN quantum dots, formed over the first section of the buffer layer, wherein the modified quantum well structure exhibits a photoluminescence spectrum simultaneously covering the primary colours of blue, green and red.

2. The diode of claim 1, wherein the quantum dots are formed by first flowing at least one of TMIn, TEIn or EDMIn at a first flow rate and a first time to form nuclei, and then flowing at least one of TMIn, TEIn or EDMIn with TMG and ammonia at a second flow rate to make the nuclei grow and be capped in the quantum wells.

3. The diode of claim 1, wherein there are between about 1 to 30 of the quantum well structures.

4. The diode of claim 1, wherein a thickness of the INₓGa₁₋ₓN quantum well layer is about 1 to 10 nm and a thickness of the IN_{y}Ga_{1-y}N quantum barrier layer is about 5 to 30 nm.

5. The diode of claim 1, wherein 1>x>y>0 or y=0.

6. The diode of claim 1, wherein the substrate is sapphire, SiC or ZnO.

7. The diode of claim 1, wherein at least one of biscyclopentadienyl magnesium, diethyl zinc or saline are used as dopants.

8. The diode of claim 1, wherein the photoluminescence spectrum covers a wavelength range of about 400 nm to 750 nm.

9. A modified quantum well structure that emits white light, which comprises:
an InₓGa₁₋ₓN quantum well layer;
InN and indium-rich InGaN quantum dots embedded in the InₓGa₁₋ₓN quantum well layer; and
an In_{y}Ga_{1-y}N quantum barrier layer over the quantum dots and the quantum well layer, wherein the modified quantum well structure exhibits a photoluminescence spectrum simultaneously covering the primary colours of blue, green and red.

10. The quantum well structure of claim 9, wherein the quantum dots are formed by first flowing at least one of TMIn, TEIn or EDMIn at a first flow rate and a first time to form nuclei, and then flowing at least one of TMIn, TEIn or EDMIn with TMG and ammonia at a second flow rate to make the nuclei grow and be capped in the quantum wells.

11. The quantum well structure of claim 9, wherein a thickness of the InₓGa₁₋ₓN quantum well layer is about 1 to 10 nm and a thickness of the In_{y}Ga_{1-y}N quantum barrier layer is about 5 to 30 nm.

12. The quantum well structure of claim 9, wherein 1>x>y>0 or y=0.

13. A process for forming a diode for emitting white light, the process comprising the steps of:
providing a substrate;
forming a buffer layer formed over the substrate, the buffer layer being divided into a first section and a second section; and
forming at least one quantum well structure comprising a modified InₓGa₁₋ₓN/In_{y}Ga_{1-y}N quantum well/barrier bilayer that encompasses InN and indium-rich InGaN quantum dots, formed over the first section of the buffer layer, the modified quantum well structure exhibiting a photoluminescence spectrum simultaneously covering the primary colours of blue, green and red.

14. The process of claim 13, wherein the quantum dots are formed by the steps of:
flowing at least one of TMIn, TEIn or EDMIn at a first flow rate and a first time to form nuclei; and
flowing at least one of TMIn, TEIn or EDMIn with TMG and ammonia at a second flow rate to make the nuclei grow and be capped in the quantum wells.

15. The process of claim 14, wherein different flow rates of TMIn, TEIn or EDMIn produce quantum wells of different sizes.

16. The diode of claim 13, wherein there are between about 1 to 30 of the quantum well structures.

17. The diode of claim 13, wherein a thickness of the InₓGa₁₋ₓN quantum well layer is about 1 to 10 nm and a thickness of the In_{y}Ga_{1-y}N quantum barrier layer is about 5 to 30 nm.

18. The diode of claim 13, wherein 1>x>y>0 or y=0.

19. The diode of claim 13, wherein the substrate is sapphire, SiC or ZnO.

20. The diode of claim 13, wherein at least one biscyclopentadienyl magnesium, diethyl zinc or silane are used as dopants
